(19) United States
(12) Patent Application Publication
(10) Pub. No.: US 2022/0352102 A1
(43) Pub. Date: Nov. 3, 2022

(54) SEMICONDUCTOR STRUCTURE AND METHOD OF FORMING THE SAME

(71) Applicant: NANYA TECHNOLOGY CORPORATION, New Taipei City (TW)

(72) Inventors: Po-Hung CHEN, Taoyuan City (TW); Cheng-Hsiang FAN, Taoyuan City (TW); Szu-Han CHEN, New Taipei City (TW); Yu-Chang CHANG, Pingtung County (TW)

(21) Appl. No.: 17/244,971

(22) Filed: Apr. 30, 2021

(51) Int. Cl. H01L 23/00

(52) U.S. Cl. CPC H01L 24/03; H01L 24/05; H01L 2224/0384; H01L 2224/03831; H01L 2224/05557

(57) ABSTRACT

A method of forming semiconductor structure includes forming a bit line structure on a substrate, forming a first landing pad material lower than the bit line structure between two adjacent bit line structures, shaping a top surface of the bit line structure to form an edge area of the top surface lower than a center area of the top surface, forming a second landing pad material on the bit line structure and the first landing pad material, and removing at least a portion of the second landing pad material to form a landing pad.

### BACKGROUND

### Field of Invention

The present disclosure relates to a semiconductor structure and a method for forming the same.

### Description of Related Art

Smaller and lighter electronics devices have driven semiconductor structures shirked with a high degree of integration. Thus, a distance between elements within the semiconductor structures has gradually decreased. The highly compact structures result in limited space for element configuration and an insufficient support for a landing pad due to lack of space may influence reliability of the semiconductor structures.

### SUMMARY

The disclosure provides a method of forming semiconductor structure. The method includes forming a bit line structure on a substrate, forming a first landing pad material lower than the bit line structure between two adjacent bit line structures, shaping a top surface of the bit line structure to form an edge area of the top surface lower than a center area of the top surface, forming a second landing pad material on the bit line structure and the first landing pad material, and removing at least a portion of the second landing pad material to form a landing pad.

The disclosure provides a semiconductor structure. The semiconductor structure includes a substrate and a bit line structure disposed on and protruding from the substrate. A top surface of the bit line structure includes a center area, an edge area lower than the center area, and a curved surface connecting the center area and the edge area. The semiconductor structure further includes a landing pad disposed on the bit line structure and between two adjacent bit line structures. The landing pad covering the curved surface of the bit line structure includes a first distance between the edge area of the bit line structure and a top surface of the landing pad, and a second distance between the center area of the bit line structure and the top surface of the landing pad. The first distance is larger than the second distance.

The disclosure provides a semiconductor structure. The semiconductor structure includes a substrate and a bit line structure disposed on and protruding from the substrate. A top surface of the bit line structure includes a center area, an edge area lower than the center area, and an inclined plane connecting the center area and the edge area. The semiconductor structure further includes a landing pad disposed on the bit line structure and between two adjacent bit line structures. The landing pad covering the inclined plane of the bit line structure includes a first distance between the edge area of the bit line structure and a top surface of the landing pad, and a second distance between the center area of the bit line structure and the top surface of the landing pad. The first distance is larger than the second distance.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is an arrangement diagram of a semiconductor structure according to some embodiments of the present disclosure.

FIG. 2A is a cross-sectional view of a semiconductor structure taken along line A-A in FIG. 1 according to some embodiments of the present disclosure.

FIG. 2B is a cross-sectional view of a semiconductor structure taken along line A-A in FIG. 1 according to some other embodiments of the present disclosure.

FIG. 3 is a flow diagram of a method for forming a semiconductor structure according to some embodiments of the present disclosure.

FIG. 4 is a cross-sectional view of a semiconductor structure at one of various formation stages according to some embodiments of the present disclosure.

FIG. 5 is a cross-sectional view of a semiconductor structure at one of various formation stages according to some embodiments of the present disclosure.

FIG. 6 is a cross-sectional view of a semiconductor structure at one of various formation stages according to some embodiments of the present disclosure.

FIG. 7 is a cross-sectional view of a semiconductor structure at one of various formation stages according to some embodiments of the present disclosure.

FIG. 8 is a cross-sectional view of a semiconductor structure at one of various formation stages according to some embodiments of the present disclosure.

FIG. 9 is a cross-sectional view of a semiconductor structure at one of various formation stages according to some embodiments of the present disclosure.

FIG. 10 is a cross-sectional view of a semiconductor structure at one of various formation stages according to some embodiments of the present disclosure.

FIG. 11 is a cross-sectional view of a semiconductor structure at one of various formation stages according to some other embodiments of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

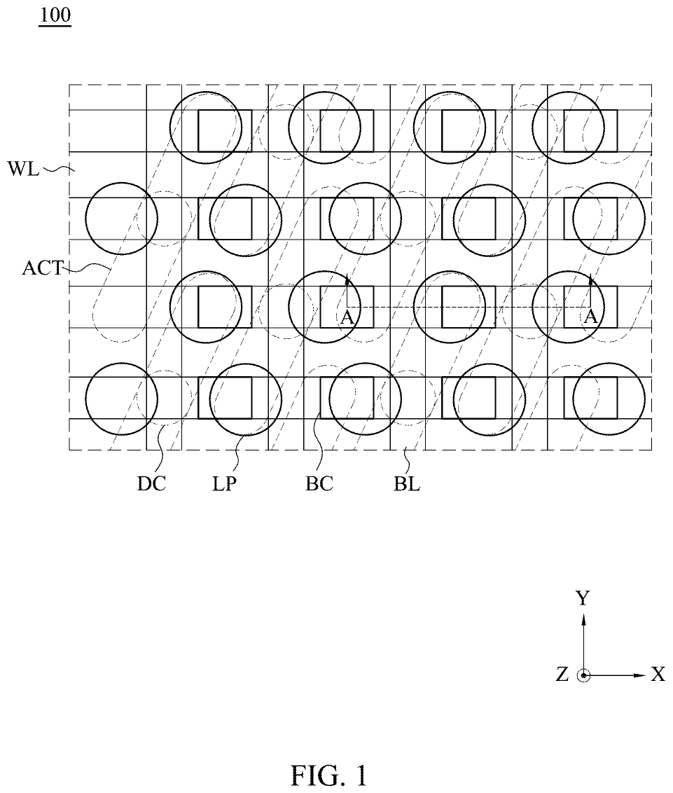

Referring to FIG. 1, FIG. 1 is an arrangement diagram of a semiconductor structure 100 according to some embodiments of the present disclosure. The semiconductor structure 100 may include a plurality of active areas ACT. The active area ACT has a short axis and a long axis. In some embodiment, the long axis of the active area ACT may extend in a diagonal axis with respect to an X axis.

A plurality of word lines WL may be configured across the active areas ACT and extend along the X axis. The word line WL is in parallel to each other. Additionally, the word line WL may be spaced apart from each other at substantially equal intervals.

A plurality of bit lines BL may be arranged above the word lines WL and may extend along a Y axis. Similarly, the lines BL is in parallel to each other. In addition, the bit line BL can be connected to the active area ACT through a direct contact DC. One active area ACT may be electrically connected to one direct contact DC.

A plurality of buried contacts BC may be formed between two adjacent bit lines BL. In some embodiments, the buried contacts BC may be spaced apart from each other along the Y axis. The buried contact BC may electrically connect a lower electrode of the capacitor (not shown) to a corresponding active area ACT. One active area ACT may be electrically connected to two buried contacts BC.

A plurality of landing pads LP may be disposed above the buried contacts BC and overlap at least a portion of a corresponding bit line BL. The landing pad may electrically connect the buried contact BC. Also, the landing pad LP may also electrically connect the lower electrode of the capacitor (not shown) to a corresponding active area ACT. In another words, the lower electrode of the capacitor (not shown) may be electrically connected to a corresponding active area ACT through a corresponding buried contact BC and a corresponding landing pad LP.

In some embodiments, one buried contact BC and one landing pad LP may collectively be referred to as a contact plug, and may be respectively referred to as a first contact plug (BC) and a second contact plug (LP).

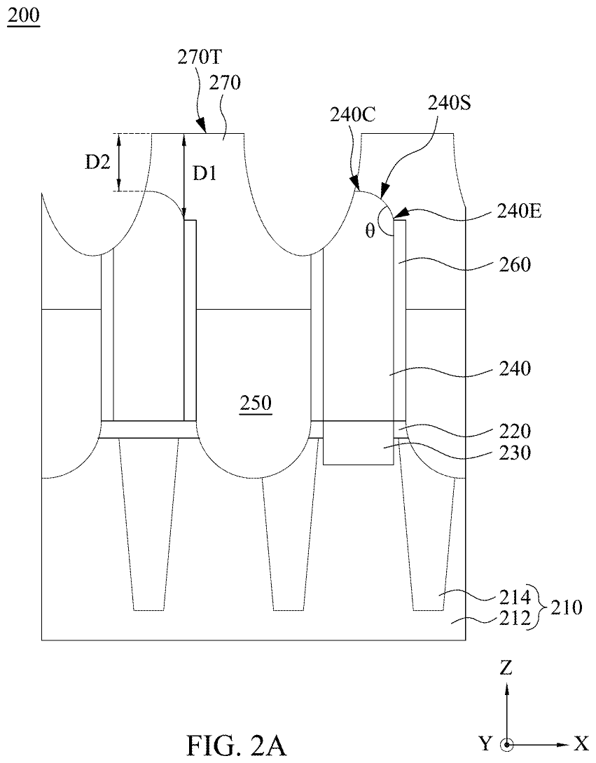

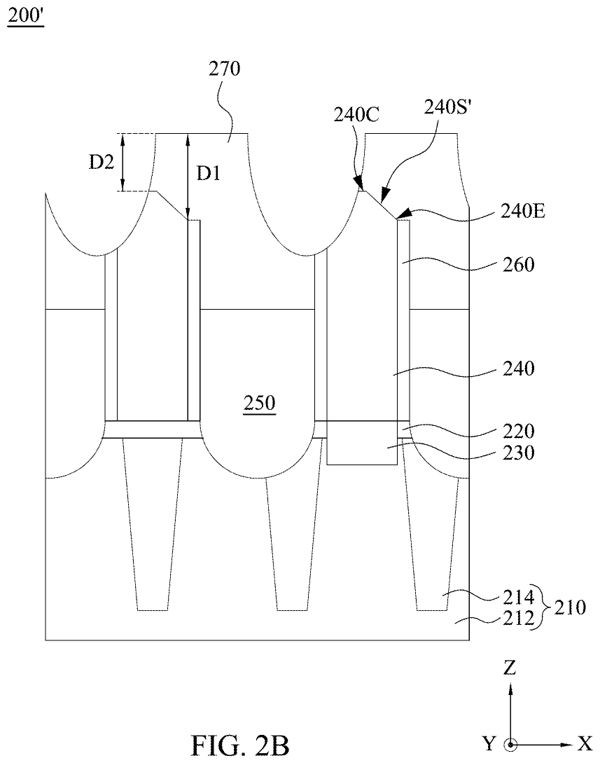

Referring to FIG. 2A, FIG. 2A is a cross-sectional view of a semiconductor structure 200 taken along line A-A in FIG. 1 according to some embodiments. The semiconductor structure 200 includes a substrate 210. The substrate 210 includes a plurality of active areas 212 (as the active areas ACT in FIG. 1) and a plurality of isolation areas 214 spacing apart the active areas 212.

The substrate 210 may include, for example, silicon (e.g., crystalline silicon, polycrystalline silicon, or amorphous silicon). In some embodiments, the substrate 210 may include elementary semiconductor (e.g., germanium), an alloy semiconductor (e.g., silicon germanium, silicon germanium carbide, gallium indium phosphide and the like), or a compound semiconductor (e.g., gallium arsenic, silicon carbide, indium phosphide, indium arsenide and the like). Further, the substrate 202 may optionally include a semiconductor-on-insulator (SOI) structure.

The isolation areas 214 may be formed through a shallow trench isolation (STI) process. The isolation areas 214 may include a material including at least one of silicon oxide, silicon nitride, and silicon oxynitride. The isolation areas 214 may be a single layer or a multilayer. For example, the isolation areas 214 may include silicon oxide and silicon nitride.

An insulation layer 220 is formed over the substrate 210 to cover a top surface of the active area 212 and isolation area 214. The insulation layer 108 is made of any suitable dielectric material, such as silicon oxide, boro-phospho silicate glass (BPSG), or traethylorthosilicate (TEOS), but the present disclosure is not limited to the above material.

During a formation of the insulation layer 220, an opening (not shown) may expose a portion of active area 212 of the substrate 210 and define a direct contact 230 (as the direct contact DC in FIG. 1). The opening (not shown) is then filled with a conductive material to form the direct contact 230. The direct contact 230 directly contacts the portion of the active area 212 of the substrate 210, leading to an electrical connection between the direct contact 230 and the active area 212.

The semiconductor structure 200 further includes a bit line structure 240 (as the bit line BL in FIG. 1) disposed on the substrate 210 and a buried contact 250 (as the buried contact BC in FIG. 1) formed between adjacent bit line structures 240. The bit line structure 240 as a first conductive structure protrudes from the substrate 210 along a Z axis and has a line-shaped structure extending along the Y axis. The buried contact 250 as a second conductive structure protrudes into the substrate 210 along the Z axis and directly contacts the portion of the active area 212. In some embodiments, the buried contact 250 has a plug-shaped structure and may be regarded as a contact plug structure.

A spacer 260 is formed on sidewalls of the bit line structure 240 between the bit line structure 240 and the buried contact 250. A spacer 260 may be a multi-layer structure made of any suitable dielectric materials. In some embodiments, an air gap is introduced into a confined space within the spacer 260 for the air gap with a dielectric constant of approximate 1 reducing parasitic capacitance between the bit line structure 240 and the buried contact 250.

The semiconductor structure 200 further includes a landing pad 270 (as the landing pad LP in FIG. 1) disposed on the bit line structure 260 and between adjacent bit line structures 240. The landing pad 270 may cover the bit line structures 240, including a portion of the sidewalls of the bit line structure 240 and a portion of a top surface of the bit line structure 240.

The top surface of the bit line structure 240 covered by the landing pad 270 includes a center area 240C, an edge area 240E, and a curved surface 240S connecting the center area 240C and the edge area 240E. In another words, the center area 240C, the edge area 240E and the curved surface 240S area are right beneath and in contact of the landing pad 270.

The edge area 240E of the top surface of the bit line structure 240 is lower than the center area 240C of the top surface of the bit line structure 240. That is, a first distance D1 between the edge area 240E of the bit line structure 240 and the top surface 270T of the landing pad 270 is larger than a second distance D2 between the center area 240C of the bit line structure 240 and a top surface 270T of the landing pad 270. Consequently, the landing pad 270 may stand on the bit line structure 240 without a risk of collapse by compromising some top portions of the bit line structure 240 (i.e., forming the curved surface 240S).

In some embodiment as illustrated in FIG. 2A, the curved surface 240S of the bit line structure 240 is a convex surface curving outward from the bit line structure 240. In some embodiments, the curved surface 240S includes an angle θ with respect to the sidewall of the bit line structure 240 in the range between about 100 and about 170°. However, a configuration of the curved surface 240S is not limited herein.

Referring to FIG. 2B, FIG. 2B is a cross-sectional view of a semiconductor structure 200′ taken along line A-A in FIG. 1 according to some other embodiments. The semiconductor structure 200′ in FIG. 2B is substantially identical to the semiconductor structure 200 in FIG. 2A. The only difference between the semiconductor structure 200′ in FIG. 2B and the semiconductor structure 200 in FIG. 2A exists in a profile of a curved surface 240S′ of the bit line structure 240 connecting the center area 240C and the edge area 240E. Specifically speaking, for the semiconductor structure 200′ as shown in FIG. 2B, the curved surface 240S′ of the top surface of the bit line structure 240 is a concave surface curving inward the bit line structure 240. Except for the curved surface 240S′, elements as well as characteristics presented in FIG. 2A can be applicable to FIB. 2B, and thus no further descriptions are elaborated therein.

In some embodiments, the curved surface 240S′ also includes the angle θ with respect to the sidewall of the bit line structure 240 in the range between about 100 and about 170°. However, a configuration of the curved surface 240S′ is not limited herein.

In some embodiments, the inclined plane 240S′ also includes the angle θ with respect to the sidewall of the bit line structure 240 in the range between about 100 and about 170°. However, a configuration of the inclined plane 240S′ is not limited herein.

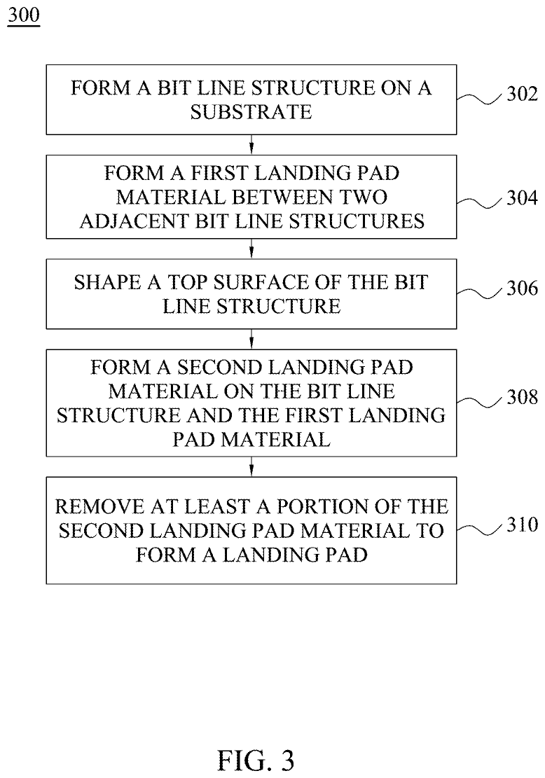

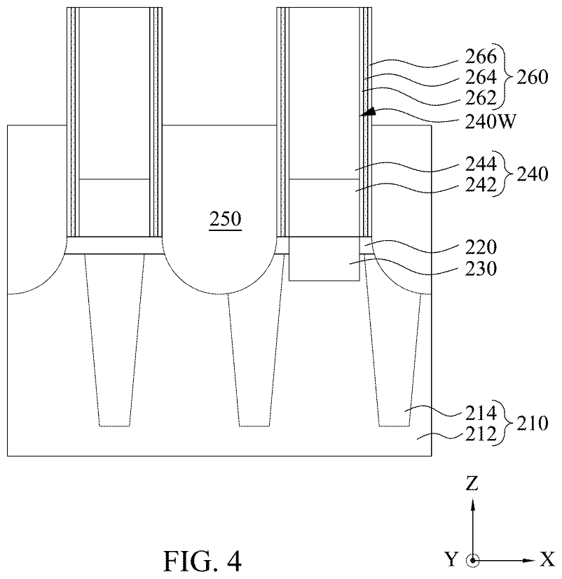

FIG. 3 is a flow diagram of a method 300 for forming a semiconductor structure (e.g., semiconductor structure 200) according to some embodiments of the present disclosure. FIG. 4 to FIG. 10 are cross-sectional views of a semiconductor structure (e.g., semiconductor structure 200) at various formation stages according to some embodiments of the present disclosure. Operations in the method 300 can be performed in a different order or not performed depending on specific applications. Additional operations can be provided before, during, and/or after the method 300, and may be briefly described herein. Further, the discussion of elements in FIG. 2A to FIG. 2B and FIG. 4 to FIG. 10 with the same annotations applies to each other, unless mentioned otherwise.

Referring to FIG. 3 and FIG. 4, the method 300 begins with operation 302 and the process of forming the bit line structure 240 on the substrate 210. The bit line structure 240 includes two portions along a vertical axis (e.g., along Z axis) substantially perpendicular to the substrate 210: a conductive layer 242 at one portion close to the substrate 210, and an insulation layer 244 at the other portion away from the substrate 210. In some embodiments, the conductive layer 242 may have a stacked structure. For example, the conductive layer 242 may be stacked with materials including doped polysilicon as well as metal nitride or metal such as tungsten, tungsten nitride, and/or titanium nitride. The insulation layer 244 includes dielectric materials, such as silicon nitride.

In an embodiment illustrated in FIG. 4, the spacer 260 is a multi-layer structure including a first layer 262, a second layer 264, and a third layer 266 sequentially deposited on sidewalls 240W of the bit line structure 240. The formation of the spacer with the multi-layer structure may include (i) depositing the first layer 262, the second layer 264, and the third layer 266 on the bit line structure 260 by any suitable approaches such as chemical vapor deposition (CVD) techniques, plasma-enhanced CVD (PECVD) techniques, atomic layer deposition (ALD), or physical vapor deposition (PVD) techniques, and (ii) removing a lateral portion (i.e., along X direction) of the first layer 262, the second layer 264, and the third layer 266 by any suitable dry etching processes and/or wet etching processes. The spacer 260 can be formed of any suitable dielectric materials. For example, the spacer 260 can be silicon nitride or silicon oxide.

The operation 302 further includes forming the buried contact 250 between the adjacent bit line structures 240. The buried contact 250 includes a silicon-containing material. In some embodiments, the buried contact 250 may include doped polysilicon.

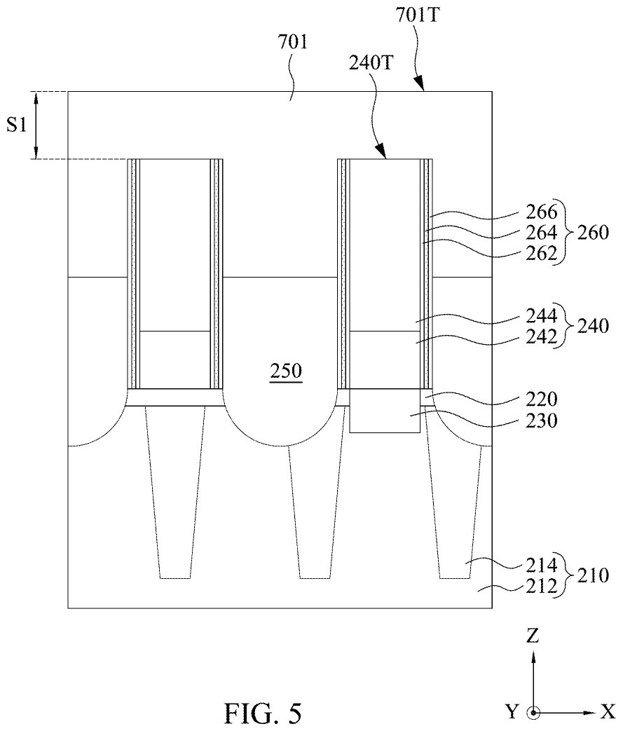

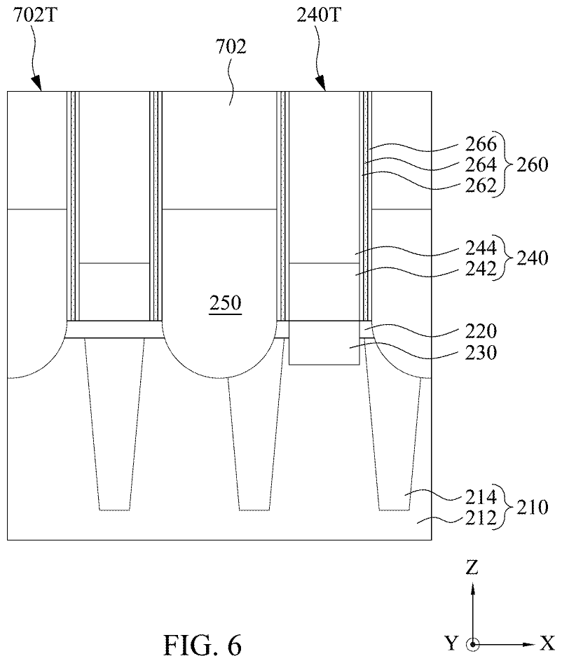

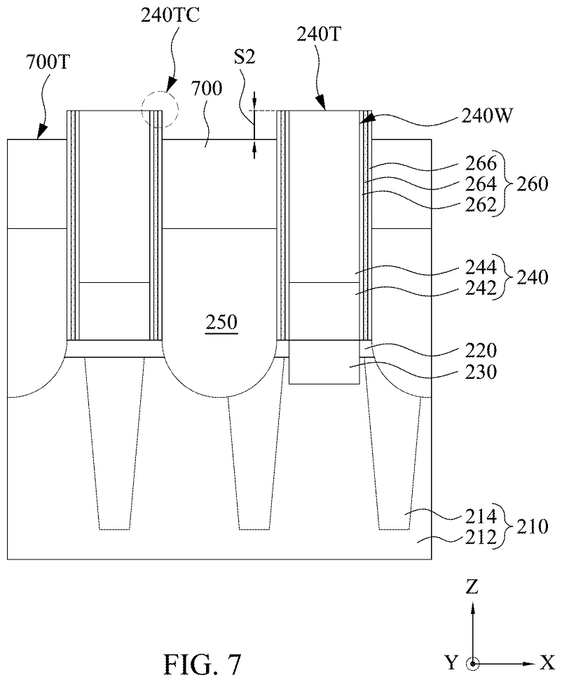

Referring to FIG. 3 and FIG. 7, the method 300 continues with operation 304 and the process of forming a first landing pad material 700 between two adjacent bit line structures 240 with the first landing pad material 700 lower than the bit line structure 240. The formation of the first landing pad material 700 is descried with reference to FIG. 5, FIG. 6 and FIG. 7.

Referring to FIG. 5, forming the first landing pad material 700 includes forming a conductive material 701 on the bit line structure and between two adjacent bit line structures. In some embodiments, a top surface 701T of the conductive material 701 is higher than a top surface 240T of the bit line structures 240 with a first distance S1 between the top surface 701T of the conductive material 701 and the top surface 240T of the bit line structures 240. The first distance S1 can be varied depend on the process design. In some embodiments, the first distance S1 ranges between about 15 nm and about 25 nm. For example, the first distance S1 may be about 20 nm. In addition, the conductive material 701 is a void-free structure.

To achieve the void-free structure, forming the conductive material 701 may include several deposition processes and etching processes. In some embodiments, a deposition/etch-back/deposition (dep/etch/dep) process is employed to deposit the conductive material 701 into a gap (not shown) between two adjacent bit line structures 240. The dep-etch-dep process involves depositing conductive material 701, followed by etching some of the conductive material 701 back to widen an opening (not shown) of the gap, and followed by re-depositing conductive material 701.

The conductive material 701 can be deposited by using CVD, ALD, PVD, or other suitable deposition process. In some embodiments, a deposition temperature used in the deposition process is in a range of about 280° C. to about 320° C. For example, the deposition temperature used in the deposition process can be 280, 290, 300, 310, or 320° C. The etching process performed after the deposition process includes using any suitable dry etching processes and/or wet etching processes. The conductive material 701 may be stacked with materials including metal nitride or metal such as tungsten, tungsten nitride, and/or titanium nitride.

Referring to FIG. 6, forming the first landing pad material 700 includes leveling the conductive material 701 to form a leveled conductive material 702 with a top surface 702T of the leveled conductive material 702 coplanar to the top surface 240T of the bit line structure 240. In some embodiments, a chemical mechanical planarization (CMP) process is used to form leveled conductive material 702. A height difference between the top surface 701T of the conductive material 701 and the top surface 702T of the leveled conductive material 702 is substantially equivalent to or greater than the first distance S1 (shown in FIG. 5) removed during a leveling process. In some embodiments where the height difference greater than the first distance S1, the top portions of the bit line structure 240 are partly removed together with the conductive material 702.

Referring to FIG. 7, forming the first landing pad material 700 includes etching the leveled conductive material 702 to form the first landing pad material 700 lower than the bit line structure 240. In another words, a top surface 700T of the first landing pad material 700 is lower than the top surface 240T of the bit line structure 240 by a second distance S2. The second distance is varied with a process design and product requirement.

The conductive material 701, the leveled conductive material 702 and the first landing pad material 700 are substantially identical to each other except for the top surface thereof due to a successive removal (e.g, the planarization process or the etching process). Thus, the first landing pad material 700 is the void-free structure based on a definition of the conductive material 701.

A top corner 240TC of the bit line structure 240 is exposed after the first landing pad is formed. In some embodiment, the top corner is above the first landing pad material 700. The top corner 240TC may be defined by sidewalls 240W and the top surface 240T of the bit line structure 240. For example, the top corner 240TC connects the sidewalls 240W and the top surface 240T of the bit line structure 240. In some embodiments, substantially horizontal top surface 240T and the substantially vertical sidewall 240W lead the top corner 240TC to be a relatively sharp corner though the top corner 240TC may not be a perfectly right-angled corner.

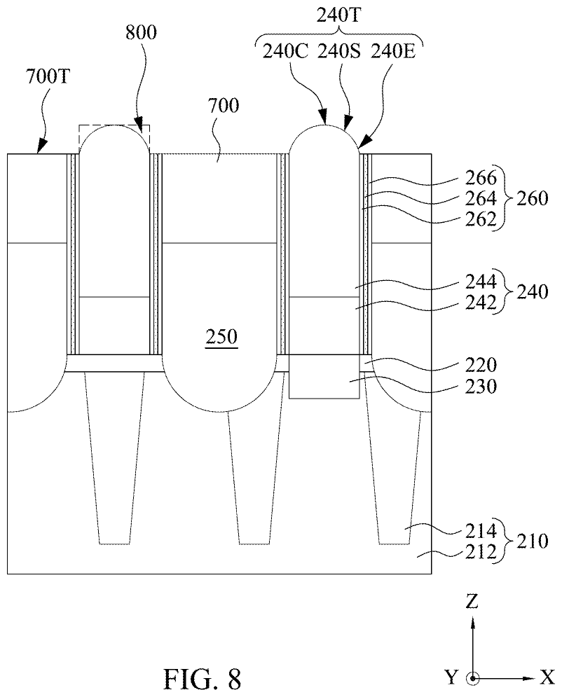

Referring to FIG. 3 and FIG. 8, the method 300 continues with operation 306 and the process of shaping the top surface 240T of the bit line structure. In some embodiments shown in FIG. 8, the top surface 240T of the bit line structure 240 may include the center area 240C, the edge area 240E lower than a center area 240C, and the curved surface 240S connecting the center area 240C and the edge area 240. The curved surface 240S of the bit line structure 240 is the convex surface curving outward from the bit line structure 240. In another words, the top surface 240T may be a relatively rounded surface. Shaping the top surface 240T of the bit line structure 240 can be achieved by removing the top corner 240TC of the bit line structure 240, and a space 800 is indicated in FIG. 8 to show a removal amount of the bit line structure 240. In addition, the space 800 implies a volume of the bit line structure 240 may be smaller after shaping.

In some embodiments, the etching process used to remove the top corner 240TC includes using plasma. The uncovered top corner 240TC is subjected to additional etch due to an etch loading effect, further reducing the space 800. In some embodiments, ion bombardment (e.g., Ar bombardment) is applied and incident upon the bit line structure 240 at a direction that is normal to the substrate 210 (i.e., an angle between a path of an ion and the substrate is not oblique).

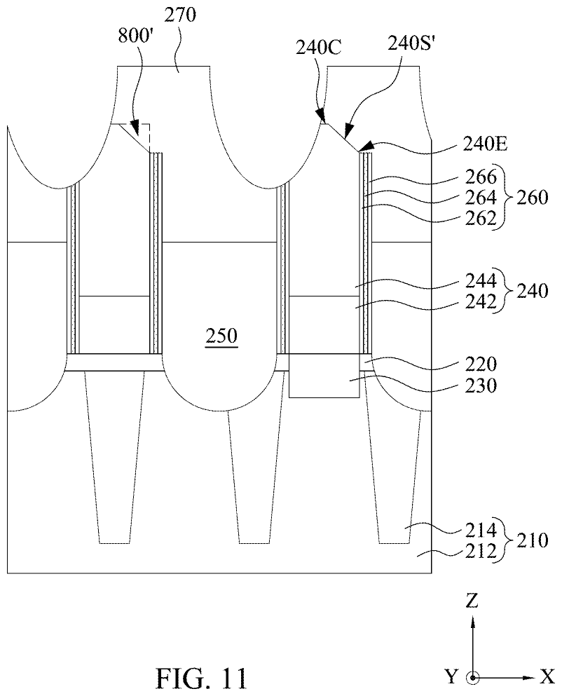

In some embodiments, the configuration of the curved surface 240S shown in FIG. 8 is for a purpose of illustration only. In accordance with some other embodiments of the present disclosure, other configurations as shown in FIG. 11 can be formed with different parameters in the etching process.

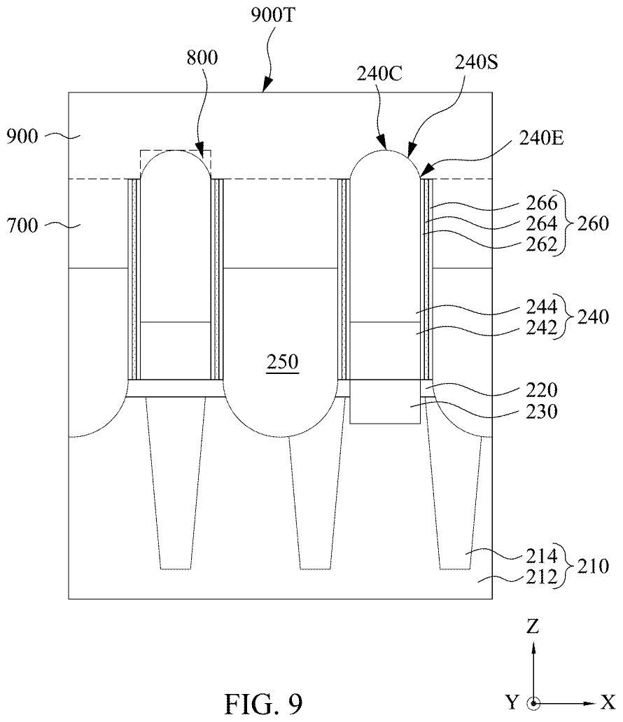

Referring to FIG. 3 and FIG. 9, the method 300 continues with operation 308 and the process of forming a second landing pad material 900 on the bit line structure 240 and the first landing pad material 700. A top surface 900T of the second landing pad material 900 is higher than the bit line structure, covering the center area 240C, the edge area 240E, and the curved surface 240S. The second landing pad material 900 directly contacts and electrically connects the first landing pad material 700. The second landing pad material 900 can be deposited by using CVD, ALD, PVD, or other suitable deposition process. Materials included in the second landing pad material 900 are substantially identical to materials included in the first landing pad material 700, and therefore no further descriptions are elaborated therein.

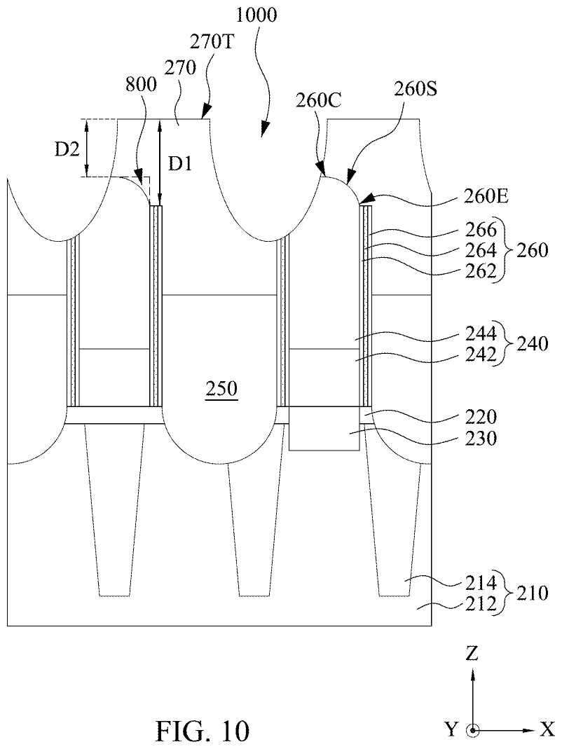

Referring to FIG. 3 and FIG. 10, the method 300 continues with operation 308 and the process of removing at least a portion of the second landing pad material 900 to form the landing pad 270. A mask pattern (not shown) may be formed on the second landing pad material 900. Subsequently, the second landing pad material 900 is etched with the mask pattern as an etch mask. In some embodiments, a portion of the bit line structure 240 (including the spacer 260 disposed on the sidewalls thereof) or a portion of the first landing pad material 700 may be removed as well. After etching, the landing pad 270 is formed and may be separated from each other by a hole 1000. In some embodiments, the top surface 270T may be similar to the top surface 900T.

Furthermore, the landing pad 270 is formed based on a combination of the first landing pad material 700 and the second landing pad material 900. Thus, the landing pad 270 can include the void-free structure.

In some embodiments, the landing pad 270 covers the top surface 240T of the bit line structure 240 including the center area 240C, the edge area 240E, and the curved surface 240S. Within the landing pad 270, the first distance D1 between the edge area 240E of the bit line structure 240 and the top surface 270T of the landing pad 270 is larger than the second distance D2 between the center area 240C of the bit line structure 240 and a top surface 270T of the landing pad 270 due to the edge area 240E lower than the center area 240C. With the above configuration, the curved surface 240S can serves as additional support for the landing pad 270 standing on the bit line structure 240 by compromising the space 800.

Referring to FIG. 11, according to some embodiments of the present disclosure, alternative parameters such as operating time or plasma intensity in the etching process are performed to remove the top corner 240TC of the bit line structure 240 in FIG. 8. For example, with longer operating time for exerting plasma on the top surface 240T of the bit line structure 240, more bit line structure 240 can be removed. A space 800′ is indicated in FIG. 11 to show the removal amount of the bit line structure 240. In addition, the space 800′ implies a volume of the bit line structure 240 may be smaller after the etching process. In the embodiments as shown in FIG. 11, the inclined plane 240S′ of the bit line structure 240 is formed with the substantially flat surface. With the above configuration, the inclined plane 240S′ can serves as additional support for the landing pad 270 standing on the bit line structure 240 by compromising the space 800′.

In some embodiments, the method 300 further includes removing the second layer 264, thereby forming an air gap (not shown) between the first layer 262 and the third layer 266. In some embodiments, a dry or wet etching process is performed to selectively remove the second layer 264 without removal of the first layer 262 and the third layer 266. Accordingly, the spacer 260 having the air gap is formed.

With the above-mentioned methods and configurations thereof, a bit line structure having a curved surface or an inclined plane on a top surface can be formed. A greater distance between the top surface of bit line structure and a top surface of a landing pad can be achieved. With the curved surface or the inclined plane, more space can be utilized for the landing pad 270 to stand on the bit line structure. Consequently, a risk of collapse of the landing pad can be eliminated.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A method of forming semiconductor structure, comprising:
forming a bit line structure on a substrate;
forming a first landing pad material between two adjacent bit line structures, wherein the first landing pad material is lower than the bit line structure;
shaping a top surface of the bit line structure to form an edge area of the top surface lower than a center area of the top surface;
forming a second landing pad material on the bit line structure and the first landing pad material; and
removing at least a portion of the second landing pad material to form a landing pad.

2. The method of forming semiconductor structure of claim 1, wherein the first landing pad material is a void-free structure.

3. The method of forming semiconductor structure of claim 1, wherein forming the first landing pad material comprises:
forming a conductive material on the bit line structure and between two adjacent bit line structures;
leveling the conductive material, wherein a top surface of the leveled conductive material is coplanar to the top surface of the bit line structure; and
etching the leveled conductive material.

4. The method of forming semiconductor structure of claim 3, wherein forming the conductive material comprises operating an etching process.

5. The method of forming semiconductor structure of claim 3, wherein forming the conductive material comprises operating a deposition process at a deposition temperature in a range of about 280° C. to about 320° C.

6. The method of forming semiconductor structure of claim 1, wherein a top corner of the bit line structure is exposed after forming a first landing pad material.

7. The method of forming semiconductor structure of claim 6, wherein shaping the top surface of the bit line structure comprises removing the top corner of the bit line structure.

8. The method of forming semiconductor structure of claim 6, wherein removing the top corner of the bit line structure comprising operating a plasma process.

9. The method of forming semiconductor structure of claim 1, further comprising removing a portion of the bit line structure or a portion of the first landing pad material.

10. A semiconductor structure, comprising:
a substrate;
a bit line structure, disposed on and protruding from the substrate, wherein a top surface of the bit line structure comprises:
a center area;
an edge area, wherein the edge area is lower than the center area; and
a curved surface, connecting the center area and the edge area; and
a landing pad, disposed on the bit line structure and between two adjacent bit line structures, wherein the landing pad covers the curved surface of the bit line structure, and comprises:
a first distance between the edge area of the bit line structure and a top surface of the landing pad; and
a second distance between the center area of the bit line structure and the top surface of the landing pad, wherein the first distance is larger than the second distance.

11. The semiconductor structure of claim 10, wherein the landing pad comprises a void-free structure.

12. The semiconductor structure of claim 10, wherein the curved surface comprises a convex surface curving outward from the bit line structure.

13. The semiconductor structure of claim 10, wherein the curved surface comprises an angle with respect to a sidewall of the bit line structure in the range between about 100° and about 170°.

14. A semiconductor structure, comprising:
a substrate;
a bit line structure, disposed on and protruding from the substrate, wherein a top surface of the bit line structure comprises:
a center area;
an edge area, wherein the edge area is lower than the center area; and
an inclined plane, connecting the center area and the edge area; and
a landing pad, disposed on the bit line structure and between two adjacent bit line structures, wherein the landing pad covers the inclined plane of the top surface of the bit line structure, and comprises:
a first distance between the edge area of the bit line structure and a top surface of the landing pad; and
a second distance between the center area of the bit line structure and the top surface of the landing pad, wherein the first distance is larger than the second distance.

15. The semiconductor structure of claim 14, wherein the landing pad comprises a void-free structure.

16. The semiconductor structure of claim 14, wherein the inclined plane comprises a substantially flat surface.

17. The semiconductor structure of claim 14, wherein the inclined plane comprises an angle with respect to a sidewall of the bit line structure in the range about 100° to about 170°.
